(19) United States
(12) Patent Application Publication
(10) Pub. No.: US 2006/0216875 A1
(43) Pub. Date: Sep. 28, 2006

(54) Method for annealing and method for manufacturing a semiconductor device

(76) Inventors: Takayuki Ito, Kawasaki-shi (JP); Kouji Matsuo, Yokohama-shi (JP); Naoki Tamaoki, Tokyo (JP); Yoshinori Honguh, Yokohama-shi (JP); Kyoichi Suguro, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/389,212

(22) Filed: Mar. 27, 2006

(30) Foreign Application Priority Data
Mar. 28, 2005 (JP) P2005-92751

(51) Int. Cl. H01L 21/84

(52) U.S. Cl. 438/149

(57) ABSTRACT

A method for annealing a semiconductor substrate by light irradiation, includes depositing a translucent film with a predetermined thickness on a semiconductor substrate. The translucent film has a refractive index that is smaller than that of the semiconductor substrate. The thickness is defined by a peak wavelength of the light and the refractive index of the translucent film. The semiconductor substrate is heated in a temperature range of about 300° C. to about 600° C. A surface of the semiconductor substrate is heated with the light which has a pulse width of about 0.1 ms to about 100 ms.

### CROSS REFERENCE TO RELATED APPLICATIONS AND INCORPORATION BY REFERENCE

This application is based upon and claims the benefit of priority from prior Japanese Patent Application P2005-092751 filed on Mar. 28, 2005; the entire contents of which are incorporated by reference herein.

### BACKGROUND OF THE INVENTION

1. Field of the Invention

The present invention relates to a method for annealing a semiconductor device, and particularly to a method for annealing and a method for manufacturing a semiconductor device using a high intensity light source.

2. Description of the Related Art

It is possible to achieve improvements in performance of a semiconductor device having a large scale integration (LSI) by increasing integration, or to put it more plainly, by miniaturization of the elements that build up a semiconductor device. Thus, LSIs are of increasingly large-scale while miniaturization of elements, such as metal-oxide-semiconductor (MOS) transistors, is being taken to a whole new level. Along with the miniaturization of elements, parasitic resistance and short channel effects on MOS transistors and the like, are increasing. Thus, there is increased importance placed on the formation of low resistance layers and shallow pn junctions.

For forming a shallow pn junction with a thickness of or below twenty nm, a thin impurity doped region is formed using an ion implantation in a semiconductor substrate with low acceleration energy. The impurities doped in the semiconductor substrate are activated by annealing, thus forming a shallow impurity diffusion region. In order to decrease layer resistance of an impurity diffusion region, it is necessary to perform activation annealing of the impurities at a high temperature.

However, the diffusion coefficients of p-type impurity such as boron (B), and n-type impurity such as phosphorus (P) or arsenic (As), in the crystal of the silicon (Si) substrate, are large. In the processing time needed to perform rapid thermal annealing (RTA) using current halogen lamps, impurities diffuse to both the interior and exterior of a semiconductor substrate. As a result, it is impossible to form a shallow impurity diffusion region having a high concentration of impurities on the semiconductor substrate. Also, it becomes impossible to activate a high concentration of impurities if the temperature of the RTA process is decreased in order to control the diffusion of the impurities. Because of such difficulties, it is difficult to form a shallow impurity diffusion region having low resistance and a high concentration of activated impurities.

Recently, a pulse light annealing method by the use of a pulse light source, such as a flashlamp and a YAG laser, which can instantly supply the energy essential to impurity activation, is being tested as a solution to the RTA problem. A xenon (Xe) flashlamp has a quartz glass tube filled with Xe gas, in which electrical charges stored in capacitors and the like, are instantaneously discharged. As a result, it is possible to emit a high intensity white light within a range of several hundred μs to several hundred ms. It is possible to attain the heat energy required for impurity activation in the instantaneous heating of a semiconductor substrate absorbing flashlamp light. Therefore, it is possible to activate a high concentration of impurities while leaving the concentration profile of the impurities, implanted into the semiconductor substrate, virtually unchanged.

However, on a semiconductor substrate, fine patterns of different materials such as polycrystalline silicon (poly-Si), silicon nitride (Si₃N₄), and silicon oxide (SiO₂) are formed in different pattern densities. Reflectivity for a flashlamp light varies depending on the pattern density of the fine patterns. For example, as the pattern density increases, the reflectivity is decreased to increase heating efficiency of the flashlamp light. If the semiconductor substrate is irradiated and sufficiently heated with the flashlamp light in order to activate impurities implanted by ion implantation, a heating temperature may be elevated in a region having the high pattern density. Thus, damage or crystal defects, such as melting, cracks, a dislocation, a stacking fault, and a slip, are induced in the semiconductor substrate.

For example, it is possible to decrease damage to the semiconductor substrate having the fine patterns by increasing an emission time of the flashlamp so as to decrease an irradiation energy density thereof. However, since the reflectivity depending on the pattern density does not change, the dependence of the heating temperature on the pattern density may still remain due to a difference in heating efficiency of the flashlamp light. As a result, an activation rate of the implanted impurities varies. As mentioned above, a current flashlamp annealing process has a problem that a variation of characteristics of elements may be induced to narrow a process window in a manufacturing process of a semiconductor device.

In a manufacturing method of a semiconductor device, a technique of forming a light absorbing film on a surface of an insulating film has been disclosed (refer to Japanese Unexamined Patent Application No. 2000-138177). However, the light absorbing film formed on the surface of the insulating film generates heat by absorbing light, and a semiconductor substrate does not generate heat. Therefore, it is difficult to instantly and efficiently increase the temperature of the semiconductor substrate.

### SUMMARY OF THE INVENTION

A first aspect of the present invention inheres in a method for annealing by light irradiation including depositing a translucent film with a predetermined thickness on a semiconductor substrate, the translucent film having a refractive index smaller than the refractive index of the semiconductor substrate, the thickness defined by a peak wavelength of the light and the refractive index of the translucent film; heating the semiconductor substrate in a temperature range of about 300° C. to about 600° C.; and heating a surface of the semiconductor substrate with the light, the light having a pulse width of about 0.1 ms to about 100 ms.

A second aspect of the present invention inheres in a method for manufacturing a semiconductor device including forming a gate insulating film on a semiconductor substrate; forming a gate electrode on the gate insulating film; implanting first impurity ions into the semiconductor substrate using the gate electrode as a mask; depositing a translucent film with a predetermined thickness on the semiconductor substrate, the translucent film having a refractive index smaller than the refractive index of the semiconductor substrate; heating the semiconductor substrate in a temperature range of about 300° C. to about 600° C.; and heating a surface of the semiconductor substrate with a light so as to activate the first impurity ions, the light having a pulse width of about 0.1 ms to about 100 ms; wherein the thickness of the translucent film is defined by a peak wavelength of the light and the refractive index of the translucent film.

### BRIEF DESCRIPTION OF DRAWINGS

FIG. 1 is a schematic view showing an example of an annealing apparatus according to an embodiment of the present invention.

FIG. 2 is a diagram showing an example of the heating property of a light source of the annealing apparatus according to the embodiment of the present invention.

FIG. 3 is a diagram showing an example of the spectrum of a light source of the annealing apparatus according to the embodiment of the present invention.

FIGS. 4 to 7 are cross sectional views showing an example of a manufacturing process for a semiconductor device used in a description of an annealing method according to the embodiment of the present invention.

FIG. 8 is a diagram showing an example of the reflectivity for an incident light through a translucent film according to the embodiment of the present invention.

FIG. 9 is across sectional view showing an example of another translucent film according to the embodiment of the present invention.

FIG. 10 is a view showing an example of a pattern of a semiconductor device according to the embodiment of the present invention.

FIG. 11 is a diagram showing an example of a cumulative probability of sheet resistance of a diffusion layer according to the first embodiment of the present invention.

FIG. 12 is a diagram showing an example of boron concentration distributions of diffusion layers after activation annealing, formed by an annealing method according to the embodiment of the present invention.

FIG. 13 is a diagram showing an example of boron concentration distributions of diffusion layers after activation annealing, formed by an annealing method of a comparative example.

FIG. 14 is a view showing an example of a cross sectional TEM image of a diffusion layer formed by an annealing method according to the embodiment of the present invention.

FIG. 15 is a diagram showing an example of a process window of irradiation energy density of an annealing method according to the embodiment of the present invention.

FIG. 16 is a view showing an example of a cross sectional TEM image of a diffusion layer of the comparative example.

FIG. 17 is a diagram showing an example of a process window of irradiation energy density according to the comparative example.

FIG. 18 is a diagram showing an example of a pattern density dependence of reflectivity for a flashlamp light incident to a surface of the semiconductor substrate from the ambient gas.

FIG. 19 is a diagram showing an example of a relation of integral reflectivity and a pattern size.

FIG. 20 is a diagram showing an example of reflectivity for a light incident through a silicon oxide film.

FIG. 21 is a diagram showing an example of reflectivity for a light incident through a silicon nitride film.

FIG. 22 is a diagram showing an example of emissivity for a flashlamp light from the semiconductor substrate.

FIG. 23 is a diagram showing an example of a spectral energy distribution of a flashlamp light received by the semiconductor substrate.

FIGS. 24 to 31 are cross section views showing an example of a manufacturing method for a semiconductor device according to the embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In an embodiment of the present invention, description will be given using an activation annealing process of the impurities implanted by ion implantation. For instance, P or As are used as n-type impurities, and B is used as p-type impurity. However, the annealing process according to the embodiment of the present invention is not limited to an impurity activation annealing process. It is obvious that annealing processes for applications such as an insulating film formation of an oxide film and a nitride film, and recrystallization of damaged layers and the like can be put into use.

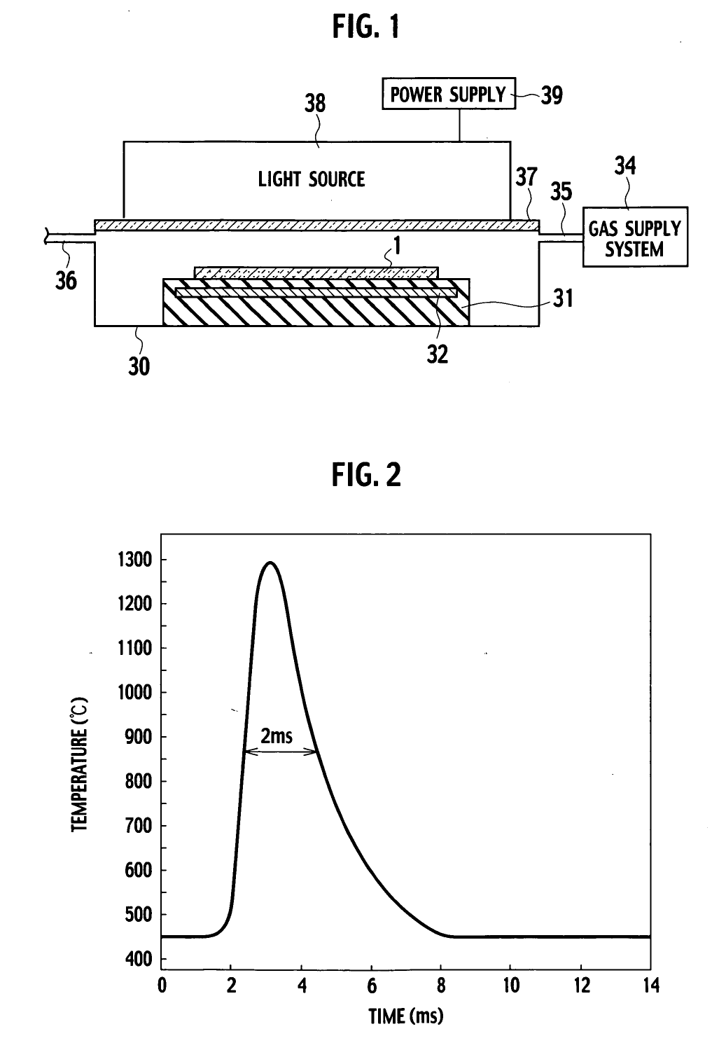

An annealing apparatus according to the embodiment of the present invention, as shown in FIG. 1, includes a processing chamber 30, a susceptor 31, an intake pipe 35, an exhaust pipe 36, a transparent window 37, and a light source 38. An annealing process is performed in the processing chamber 30 to activate impurity ions implanted into a semiconductor substrate 1, such as a Si substrate. The semiconductor substrate 1 is placed on top of the susceptor 31 which is disposed inside of the processing chamber 30. The intake pipe 35 feeds an ambient gas to the processing chamber 30. The exhaust pipe 36 vents the ambient gas from the processing chamber 30. The transparent window 37 is disposed on top of the processing chamber 30 facing the susceptor 31. The light source 38 irradiates a pulse of light through the transparent window 37 to a surface of the semiconductor substrate 1.

The processing chamber 30 is fabricated from a metal such as stainless steel. The susceptor 31, on which the semiconductor substrate 1 is placed, is located on the bottom of the processing chamber 30. Aluminum nitride (AlN), ceramics, quartz glass, and the like, may be used as the susceptor 31. Also, the susceptor 31 may be stainless steel with a surface protected by AlN, ceramics, or quartz glass. A heat source 32 used to heat the semiconductor substrate 1 is provided in the susceptor 31. A hot plate, an embedded metallic heater of nichrome wire, a heating lamp such as a halogen lamp, are used as the heat source 32. Temperature of the heat source 32 is controlled by a control system (not shown) provided outside of the processing chamber 30. A gas supply system 34 including a gas source that supplies an inert gas during the annealing of the semiconductor substrate 1 is connected to the intake pipe 35.

The light source 38, such as a flashlamp, irradiates a pulsed light through the transparent, synthetic quartz window 37 and the like, onto the surface of the semiconductor substrate 1, to heat the semiconductor substrate 1. The power supply 39, such as a pulse power supply, drives the light source 38 at an extremely short pulse width. The full width at half maximum (FWHM) of the pulse is about 0.1 ms to about 100 ms. The power supply 39 controls the irradiation energy and pulse width of the light beamed from the light source 38. The energy density of the light source 38 is within the range of about 5 J/cm² to about 100 J/cm². The transparent window 37 transmits the light from the light source 38 to the semiconductor substrate 1 while maintaining an airtight barrier separating the processing chamber 30 from the light source 38.

On the annealing process used to activate impurities implanted by ion implantation, when irradiating the semiconductor substrate with an emitted light having a FWHM less than about 0.1 ms from the light source 38, an irradiation energy density of the emitted light for heating to an activation annealing temperature is increased so that the thermal stress induced in the semiconductor substrate 1 is increased. Further, when the FWHM of the emitted light exceeds 100 ms, the diffusion of the implanted impurities is enhanced.

In activation annealing, the semiconductor substrate 1, placed on top of the susceptor 31, is preheated by the heating source 32 within a temperature range of about 300° C. to about 600° C., and desirably at about 400° C. to about 500° C. The preheating is set to a temperature that does not cause damage to the semiconductor substrate 1. If a preheating temperature is less than about 300° C., an irradiation energy density of the light source 38 for heating to an activation annealing temperature is increased. As a result, crystal defects, such as slips and dislocations, which are caused by thermal stress, are easily generated in the semiconductor substrate 1. Further, if the preheating temperature exceeds 600° C., the implanted impurities may be diffused during the preheating.

Moreover, a desirable heating rate of the preheating is less than about 20° C./s. If the heating rate exceeds 20° C./s, the semiconductor substrate 1 is warped, deformed and easily damaged.

Furthermore, in activation annealing, a light source 38 emits a light to irradiate the semiconductor substrate 1 with only one pulsed light beam. If a FWHM of the pulsed light beam is about 2 ms, an irradiation energy density is, for example, within a range from about 28 J/cm² to about 36 J/cm² and a range from about 18 J/cm² to about 26 J/cm² at the preheating temperature of about 300° C. and about 600° C., respectively. Further, the irradiation energy density is within a range from about 20 J/cm² to about 33 J/cm² at the preheating temperature of about 450° C. In the description of the embodiment of the present invention, activation annealing conditions are a preheating temperature of about 450° C. and an irradiation energy density of about 25 J/cm², for example

As shown in FIG. 2, at about 1300° C. for example, which is the highest temperature reached by the heating provided by the Xe flashlamp used as the light source 40, a thermal profile having a FWHM of about 2 ms can be attained. In the Xe flashlamp, it is possible to achieve precipitous increases and decreases in temperature compared to an infrared lamp such as a halogen lamp used in RTA. The thermal elevation time for an increase or a decrease of temperature between about 450° C. to about 1300° C. is more than about 10 s, for example about 15 s with the halogen lamp light. Additionally, a thermal elevation time of about two seconds to about three seconds is required for the increase or the decrease of temperature between about 900° C. and about 1300° C. On the other hand, with the flashlamp light, the thermal elevation time required for a temperature between about 450° C. and about 1300° C. is between about 0.1 ms and about 100 ms, and desirably between about 0.5 ms to about 50 ms. Here, the surface temperature of the semiconductor substrate 1 is measured by a high-speed pyrometer.

In the embodiment of the present invention, it is possible to activate the implanted impurities in the semiconductor substrate 1 at a high temperature of about 900° C. or more in an extremely short period of time. As a result, impurity diffusion arising from activation annealing can be limited to a depth of about 5 nm or less. Thus, it is possible to form a shallow pn junction.

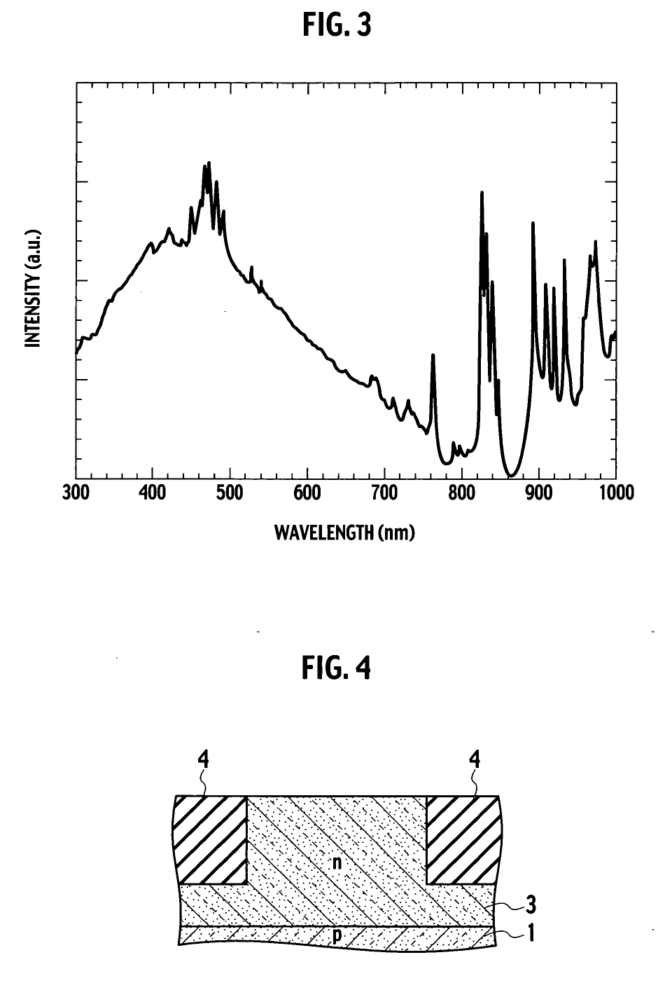

The luminous spectrum of the Xe flashlamp of the light source 38 is close to that of white light, and has a main peak intensity wavelength from about 400 nm to about 500 nm, as shown in FIG. 3. Light in a peak intensity wavelength range below about 1 μm of the flashlamp is mainly absorbed in a region ranging from the surface of the semiconductor substrate 1 to a depth of about 0.1 μm. Rapid temperature increases locally occur in the region ranging from the surface of the semiconductor substrate 1 to a depth of several tens μm. As a result of the rapid temperature increases, a thermal difference of between about 300° C. and about 1000° C. occurs between the top and bottom surfaces of the semiconductor substrate 1. The thermal difference causes an increase in the thermal stress in the interior of the semiconductor substrate 1.

For example, a plurality of regions each having a different pattern density of element patterns are formed on the surface of the semiconductor substrate 1. Since a reflectivity for the flashlamp light depends on the pattern density, the semiconductor substrate 1 is not uniformly heated. In particular, in a region where the element patterns are densely arranged, reflectivity for the flashlamp light is smaller, so as to heat to a higher temperature. In this way, when activation annealing is performed on the semiconductor substrate 1 where the pattern density is not uniform, by use of the light source 38, implanted impurities are not uniformly activated, and the element characteristics vary. Further, due to crystal defects resulting from a thermal stress inside the semiconductor substrate 1, the semiconductor substrate 1 is easily damaged.

Next, an annealing method according to the embodiment of the present invention will be described using a manufacturing process of a p-MOS transistor as an example. Further, the semiconductor device is not limited to a p-MOS transistor. A semiconductor device such as an n-MOS transistor and a complementary MOS (CMOS) transistor, for instance, are also within the scope of the invention. Additionally, a metal-insulator-semiconductor (MIS) transistor using an insulating film such as a silicon oxynitride (SiON) film, a Si₃N₄ film, or a composite insulating film between a SiO₂ film and a SiON film, a Si₃N₄ film, a various metal oxide film or the like, instead of the SiO₂ film, is also within the scope of the invention.

As shown in FIG. 4, ions of an n-type impurity atom of a group V element, such as P, are implanted into a p-type semiconductor substrate 1 of Si, so as to form an n-well 3. By photolithography, reactive ion etching (RIE) and the like, a trench is formed on a periphery of the n-well 3. By low pressure chemical vapor deposition (LPCVD) and the like, an insulating film, such as SiO₂, is deposited so as to bury the trench. Afterward, the insulating film deposited on the surface of the n-well 3 of the semiconductor substrate 1 is removed by chemical mechanical polishing (CMP) and the like, so as to form a shallow trench isolation (STI) 4 as an isolation region. An element region is formed in between the STI 4.

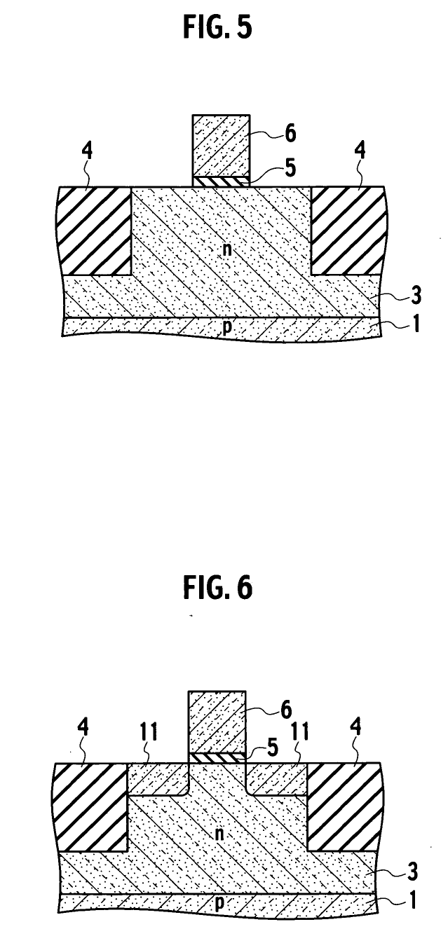

As shown in FIG. 5, an insulating film, such as thermal oxide, is formed on the surface of the element region of the semiconductor substrate 1. A poly-Si film is deposited on top of the insulating film by LPCVD and the like. The poly-Si film and the insulating film are selectively removed by photolithography, RIE and the like, so as to form a gate electrode 6 and a gate insulating film 5.

As shown in FIG. 6, using the gate electrode 6 as a mask, an ion implantation process for a diffusion layer is implemented. Ions of a group III element, such as B, as the p type impurities are implanted in the exposed surface of the semiconductor substrate 1. For instance, B ion implantation conditions are an acceleration energy of about 0.5 keV, and an implant dose of 1×10¹⁵ cm⁻². As a result, impurity implanted layers 11 having a depth of about 15 nm from the surface of the semiconductor substrate 1 are formed in between the gate insulating film 5 and the STI 4.

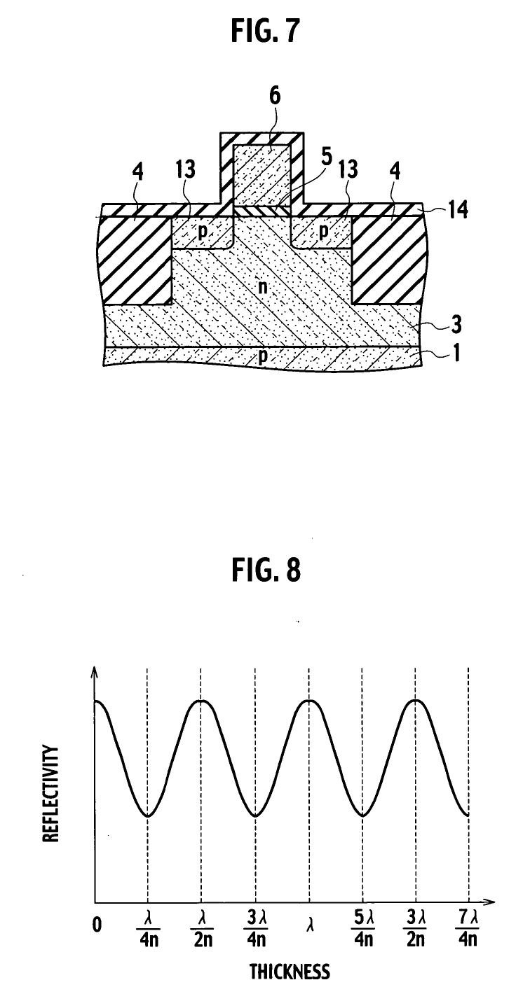

As shown in FIG. 7, by LPCVD and the like, a translucent film 14, such as SiO₂, is deposited on the surface of the semiconductor substrate 1 in which the STI 4 and the gate electrode 6 are formed. A deposition condition of the translucent film 14 is a temperature of less than about 600° C. The semiconductor substrate 1 is placed on top of the susceptor 31 of the annealing apparatus shown in FIG. 1. In activation annealing, the semiconductor substrate 1 is preheated to about 450° C., for example, from a bottom surface of the semiconductor substrate 1 by the heat source 32 of the susceptor 31. The top surface of the semiconductor substrate 1 is irradiated by a flashlamp light from the light source 38 with a pulse width of about two ms and an irradiation energy density of about 25 J/cm², while maintaining the preheating temperature of about 450° C. By activation annealing, the B ions implanted in the impurity implanted layers 11 are diffused and located in substitutional lattice sites to be activated. As a result, p-type diffusion layers 13 are formed between both ends of the gate insulating film 5 and the STI 4.

In an annealing method according to an embodiment of the present invention, the flashlamp light emitted from the light source 38 is irradiated from above the surface of the semiconductor substrate 1. Then, the flashlamp light is transmitted through a translucent film 14 from an ambient gas in the processing chamber 30, and absorbed by the gate electrode 6 and the impurity implanted layer 11. The light transmittance of SiO₂ used for the translucent film 14 is about 90% or higher. Therefore, it is possible to suppress an energy loss of the light transmitted through the translucent film 14 toward the semiconductor substrate 1.

Further, a refractive index of the ambient gas of the processing chamber 30 is about one, and the refractive index of Si used for the semiconductor substrate 1 is about four to five. A difference between the refractive indices is large. For example, when irradiating the flashlamp light to the semiconductor substrate 1 directly from the ambient gas, reflectivity at the surface of the semiconductor substrate 1 becomes larger in accordance with the difference of refractive index. The refractive index of SiO₂ used for the translucent film 14 is about 1.4, which is an intermediate value between the refractive indices of the ambient gas and Si. Therefore, when irradiating the flashlamp light to the semiconductor substrate 1 through the translucent film 14 having a refractive index as an intermediate value between the refractive indices of the ambient gas and the semiconductor substrate 1, reflectivity at the translucent film 14 and at the surface of the semiconductor substrate 1 is reduced.

Further, the flashlamp light is irradiated to the translucent film 14 which covers the gate electrode 6 and the impurity implanted layers 11. Therefore, reflectivity of the entire surface above the semiconductor substrate 1 is made uniform, so that the pattern density dependence of reflectivity is reduced. Thus, it is possible to suppress local heating.

As mentioned above, the gate electrode 6 and the impurity implanted layers 11, which uniformly absorb the flashlamp light, are uniformly heated. Temperatures of the gate electrode 6 and the impurity implanted layers 11 instantaneously exceed 1100° C., so as to electrically activate the impurities implanted into the gate electrode 6 and the impurity implanted layers 11. By activating the impurities, resistances of the gate electrode 6 and the diffusion layers 13 are uniformly decreased. As described above, according to the embodiment of the invention, it is possible to suppress crystal defects generated in the semiconductor substrate 1 and to form a shallow pn junction. As a result, activation annealing can be carried out with high uniformity and a high yield rate.

In addition, reflectivity at a boundary between the translucent film 14 and the semiconductor substrate 1 can be reduced by adjusting the film thickness of the translucent film 14. The reflectivity at the boundary between the translucent film 14 and the semiconductor substrate 1 varies relative to the film thickness at a cycle of λ/(2*n). Here, λ denotes a peak wavelength of incident light, and n denotes a refractive index of the translucent film 14. A film thickness dₘᵢₙ that minimizes the reflectivity is defined by the wavelength λ and the refractive index n of the translucent film 14, as follows:
dₘᵢₙ=(2j−1)*λ/(4n), (1)
where j is an arbitrary positive integer.

As shown in FIG. 3, the flashlamp light of the light source 38 is a continuous spectrum, which has a main emission light intensity in a visible light range with a peak wavelength of about 450 nm. For example, the refractive index n of SiO₂ is about 1.4. The film thickness dₘᵢₙ that minimizes the reflectivity is about 80 nm when j is 1. Accordingly, the film thickness of the translucent film 14 is determined based on Expression (1), so that the flashlamp light incident on the translucent film 14 is converted with higher efficiency into heat energy in the semiconductor substrate 1. As a result, heating efficiency of the semiconductor substrate 1 can be improved.

The film thickness d of the translucent film 14 is desirably set so as to satisfy conditions of the following expression that is defined by the peak wavelength λ, and the refractive index n of the translucent film 14.
(2j−1)*λ/(4n)−λ/(8n)<d<(2j−1)*λ/(4n)+λ/(8n) (2)
When the film thickness d of the translucent film 14 is within a range defined by Expression (2), the pattern density dependence of the semiconductor substrate 1 is suppressed. As a result, the semiconductor substrate 1 can be highly uniformly heated.

In the above explanation, a SiO₂ film is used as the translucent film 14. However, as the translucent film 14, any transparent film having a refractive index as an intermediate value between the refractive indices of the ambient gas and the semiconductor substrate 1 can be used. For example, a Si₃N₄ film having a refractive index of about two, and a carbon doped silicon oxide (SiOC) film having a refractive index equivalent to that of the SiO₂ film, and the like, can be used.

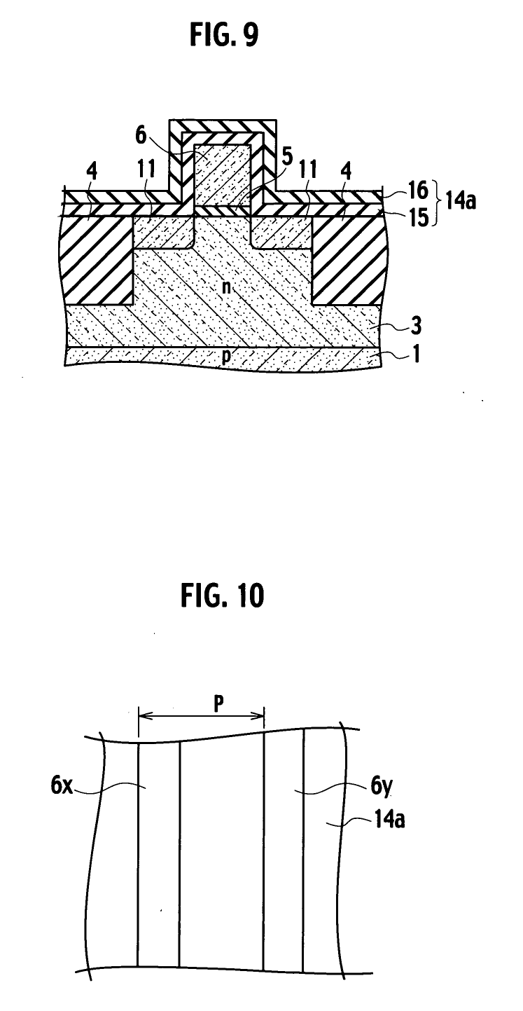

As the translucent film, a multilayer film which includes a plurality of insulating films, such as SiO₂, Si₃N₄, and SiOC, may be used. For example, as shown in FIG. 9, a translucent film 14a includes a first insulating film 15 and a second insulating film 16. In this case, respective refractive indices n₁ and n₂ of the first and second insulating films 15 and 16 desirably satisfy the following inequality.
nₐₜₘ<n₁<n₂<n_{Si}, (3)
where nₐₜₘ and n_{Si} denote refractive indices of the ambient gas and Si, respectively. Each of the differences in refractive indices between the ambient gas, the first insulating film 15, the second insulating film 16, and the semiconductor substrate 1 can be decreased, so that reflectivity at the interface of the semiconductor substrate 1 can be reduced.

Additionally, film thicknesses d₁ and d₂ of the first and second insulating films 15 and 16 are desirably provided to satisfy conditions of the following expressions.
(2j−1)*λ/(4n₁)−λ/(8n₁)<d₁<(2j−1)*λ/(4n₁)+λ/(8n₁) (4)
(2k−1)*λ/(4n₂)−λ/(8n₂)<d₂<(2k−1)*λ/(4n₂)+λ/(8n₂), (5)
where each of j and k is an arbitrary positive integer.

For example, as shown in FIG. 9, the translucent film 14a including the first and second insulating films 15 and 16 is formed on the surface of the gate electrode 6 and the impurity implanted layer 11. The first and second insulating films 15 and 16 are a Si₃N₄ film with a thickness of about 60 nm and a SiO₂ film with a thickness of about 80 nm, respectively. To examine an influence of the translucent film 14a, activation annealing is carried out to samples prepared by depositing translucent films having the same structure as the translucent film 14a on element patterns having different pattern densities on respective semiconductor substrates.

As the element pattern, as shown in FIG. 10, a line and space (L/S) pattern where a plurality of gate electrodes 6x and 6y are arranged at a pitch P is used. For example, a pattern A at the pitch P of about 200 nm and a pattern B at the pitch P of about 110 nm are formed on the semiconductor substrate, such as a Si substrate. A pattern density of the pattern B is larger than the pattern A. Further, a Si substrate without pattern is also used. As a comparative example, activation annealing is carried out to each of samples having the pattern A, the pattern B, and the sample without a pattern, before depositing translucent films. After activation annealing, a diffusion layer corresponding to the impurity implanted layer 11 is evaluated. Activation annealing conditions are a preheating temperature of about 450° C. and an irradiation energy density of about 25 J/cm².

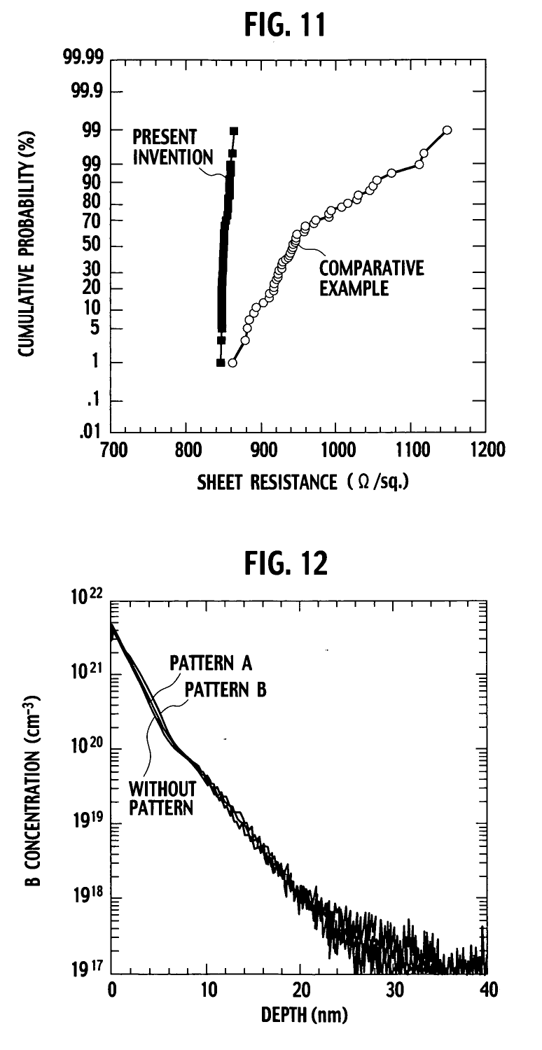

In order to check activation of impurities of the diffusion layer, sheet resistance is measured. As shown in FIG. 11, in any sample of the embodiment of the present invention, sheet resistance of the diffusion layer of each of a plurality of elements formed on the Si substrate is as low as about 850 Ω/sq. Further, in-plane variation σ of the sheet resistance of the plurality of elements is suppressed to less than about 1%. On the other hand, in the samples of the comparative example, the sheet resistance is as high as about 860 Ω/sq to about 1150 Ω/sq. The in-plane variation σ is as large as about 6%. Thus, according to the embodiment of the present invention, efficient activation can be performed, and variations in electrical characteristics of the diffusion layer can be suppressed.

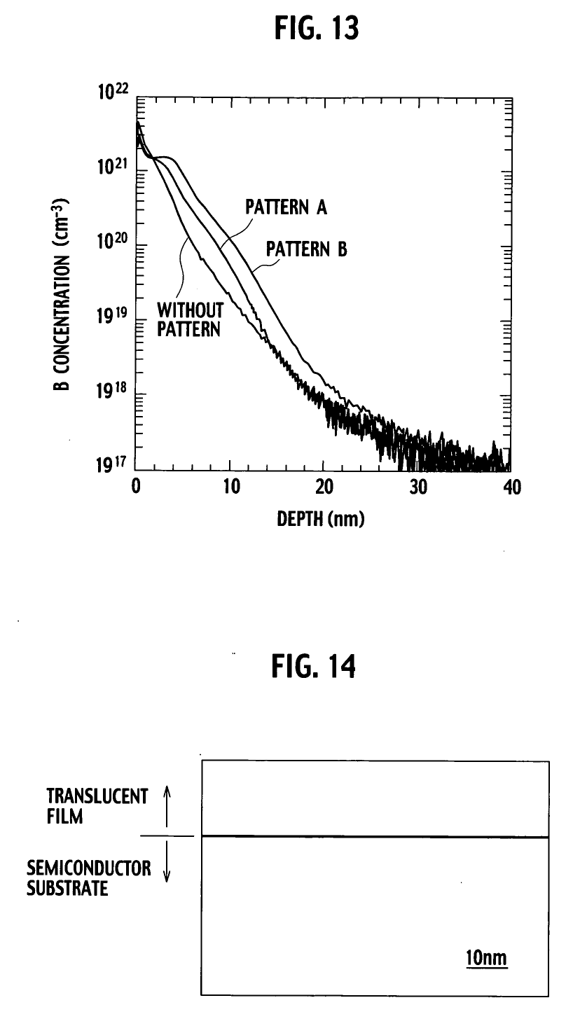

An impurity concentration profile of the diffusion layer of each sample of the embodiment of the present invention and the comparative example is measured by secondary ion mass spectrometry (SIMS). In the embodiment of the present invention, as shown in FIG. 12, there is no significant difference in depth of the diffusion layers among the samples having the pattern A, the pattern B, and without a pattern, and there is almost no pattern density dependence. In the comparative example, as shown in FIG. 13, depth of the diffusion layer varies depending on the pattern density. The depth of the diffusion layer of the sample having the pattern B, which has the highest pattern density, is the largest. The depth of the diffusion layer of the sample without a pattern is the smallest. As mentioned above, according to the embodiment of the present invention, it is possible to suppress the pattern density dependence on the depth of the diffusion layer.

The samples subjected to the activation annealing were observed for crystal defects, such as dislocations, by transmission electron microscope (TEM). As shown in FIG. 14, in a cross sectional TEM image of the diffusion layer according to the embodiment of the present invention, it is confirmed that there is no crystal defects in the semiconductor substrate below the translucent film, and crystalline recovery is achieved.

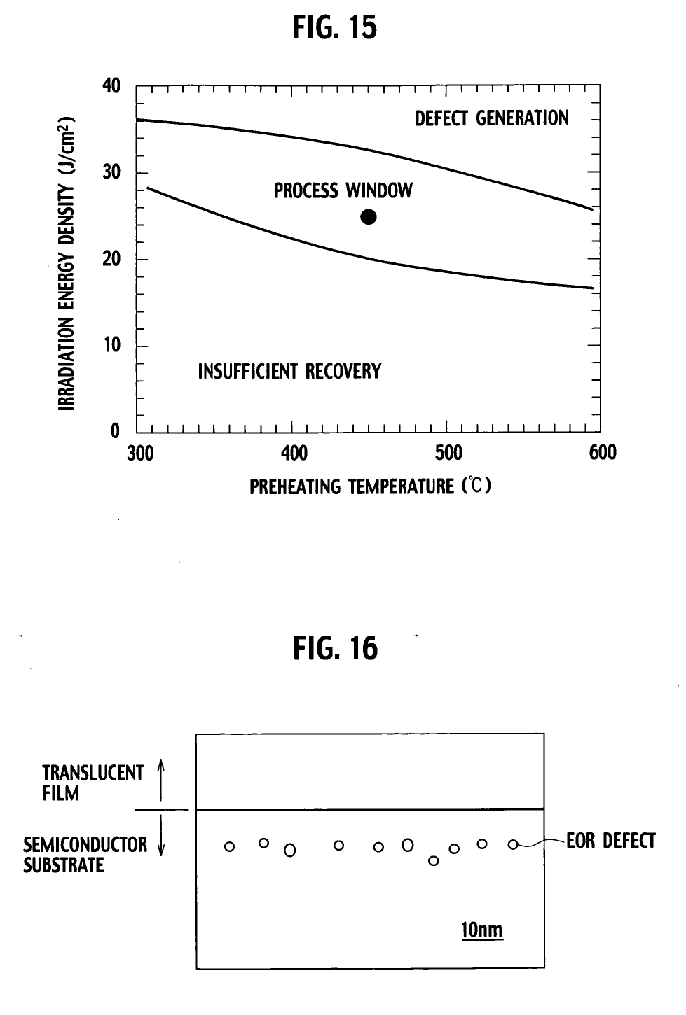

Further, the semiconductor substrate, on which the translucent film is formed, is subjected to activation annealing with various preheating temperatures and irradiation energy density, to observe crystal defects. As shown in FIG. 15, based on the observation result, it is confirmed that there is a process window for an activation annealing condition, in which no crystal defects are generated, with respect to the preheating temperature and the irradiation energy density. When the irradiation energy density is lower than the range of the process window, recovery of crystal defects generated by ion implantation is insufficient and activation efficiency is also low. Further, when the irradiation energy density is higher than the range of the process window, crystal defects such as slip and dislocation occur due to thermal stress. In addition, the higher the preheating temperature, the lower the irradiation energy density for the process window. It is confirmed that an activation annealing condition of the embodiment of the present invention is within the range of the process window as indicated by a solid circle in FIG. 15.

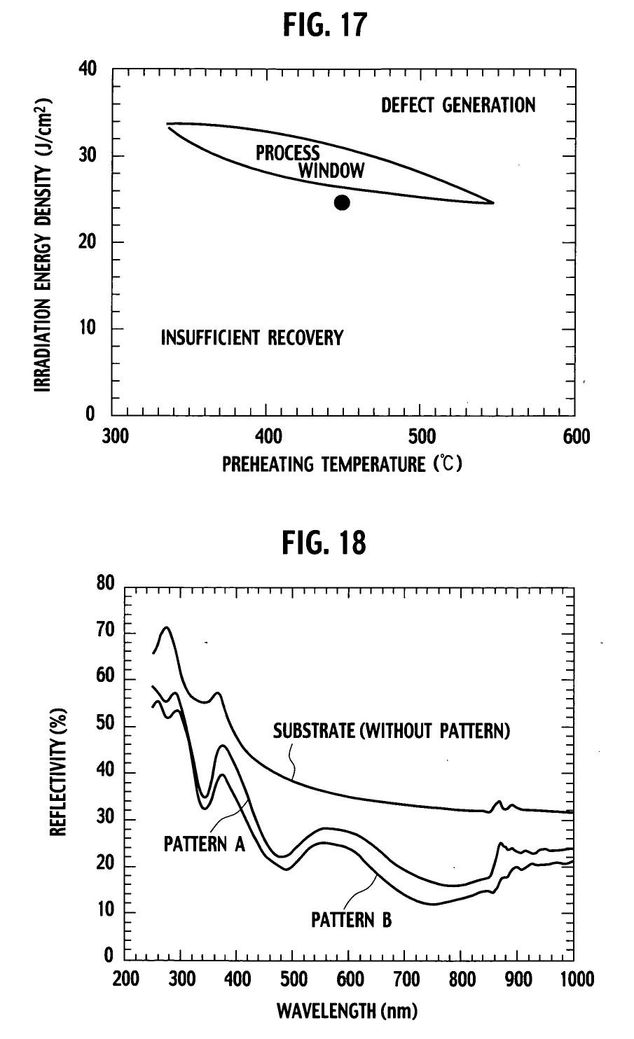

On the other hand, as shown in FIG. 16, in a cross sectional TEM image of the diffusion layer of the comparative example, end of range (EOR) defects which are clusters of defects, such as dislocation, generated by ion implantation is observed in the semiconductor substrate below the translucent film. Further, when the semiconductor substrate is annealed without using the translucent film, a range of the process window becomes narrower than that of the embodiment of the present invention, as shown in FIG. 17. It is confirmed that an activation annealing condition of the comparative example is not within the range of the process window as indicated by a solid circle in FIG. 17.

In the comparative example, the semiconductor substrate is irradiated with the flashlamp light without the translucent film. As shown in FIG. 3, the flashlamp light is a continuous spectrum ranging from a near-ultraviolet region to a near-infrared region. For example, as shown in FIG. 18, reflectivity of the flashlamp light incident to the surface of the semiconductor substrate from the ambient gas varies from the near-ultraviolet region to the near-infrared region, depending on the pattern density on the surface of the semiconductor substrate.

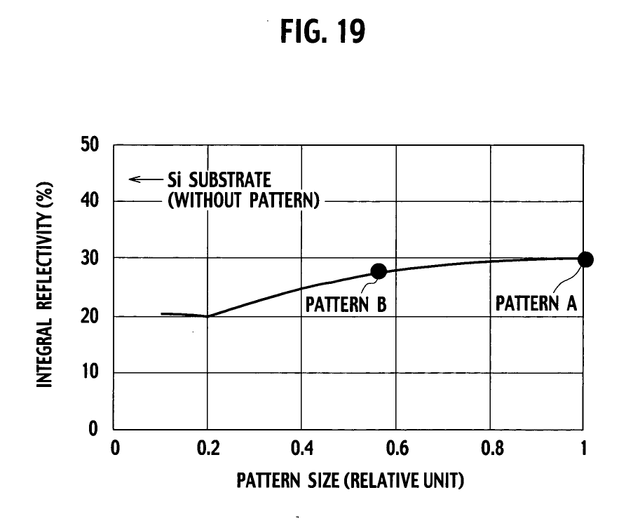

As shown in FIG. 19, an integral reflectivity, which is standardized by integrating the reflectivity values in a wavelength range of about 250 nm to about 1000 nm, is smaller in the pattern B than in the pattern A. The pattern B has a smaller pattern size corresponding to the pitch P shown in FIG. 10 than the pattern A. Thus, the heating efficiency by the irradiation energy of the flashlamp light varies, depending on the pattern size. More specifically, the temperature tends to increase with the dense pattern, and the temperature barely increases with the sparse pattern. As a result, in activation annealing using the flashlamp light, a pattern density dependence occurs.

Further, in the Si substrate without a pattern, the flashlamp light is incident to the Si substrate having a high refractive index of four to five from the ambient gas having a refractive index of about one. Accordingly, the flashlamp light is extremely reflected at the surface of the Si substrate. As a result, the heating efficiency of the Si substrate without a pattern is considerably decreased.

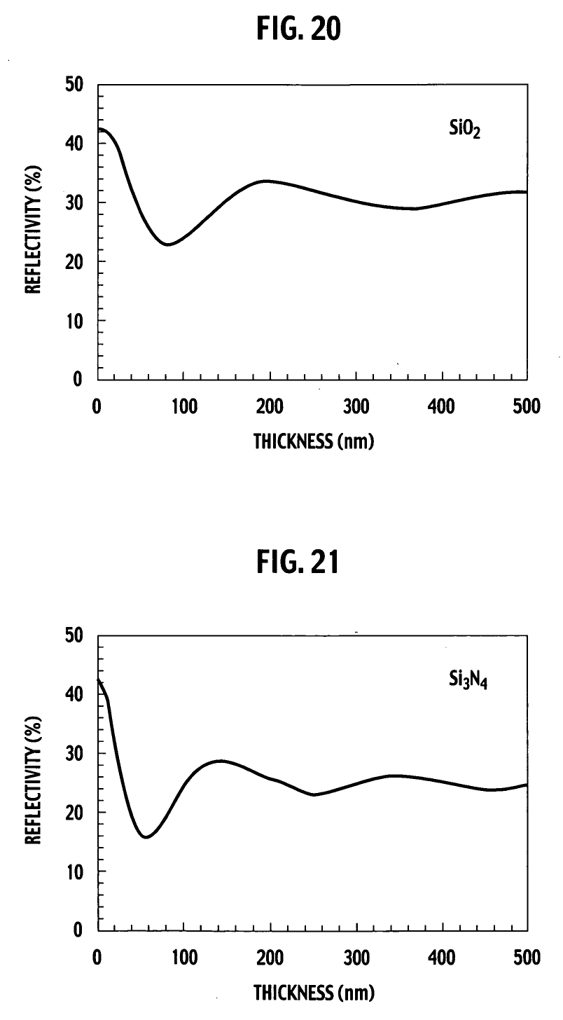

In practice, the flashlamp light is a continuous spectrum light having a wide wavelength range as shown in FIG. 3. In the case of the continuous spectrum light, as shown in FIGS. 20 and 21, reflectivity oscillates with the thickness of the translucent film so as to converge to a constant value. The oscillation amplitude of the reflectivity is gradually attenuated. When a SiO₂ film and a Si₃N₄ film are the translucent film, values of reflectivity at the interface of the semiconductor substrate are the lowest with thicknesses of about 80 nm and about 50 nm, respectively, corresponding to {λ/(4n)}. Further, the values of reflectivity are maintained at substantially constant values with thicknesses of {3λ/(4n)} or larger.

In this way, for the flashlamp light having a wide wavelength range, variations in reflectivity with respect to a thickness of the translucent film are reduced with the condition that the value of the thickness of the translucent film exceeds a fixed value. Therefore, it is desirable to select the thickness of the translucent film 14 to be about {λ/(4n)} so as to provide the minimum reflectivity, when priority is given to the heating efficiency. On the other hand, when the thickness of the translucent film 14 is selected as {3λ/(4n)} or more, the variations in reflectivity with respect to the thickness variation of the translucent film 14 can be suppressed. Accordingly, for designing a process condition of activation annealing, robust design for optimizing a process condition can be made, and the annealing method is more practical from the viewpoint of manufacture of the semiconductor device.

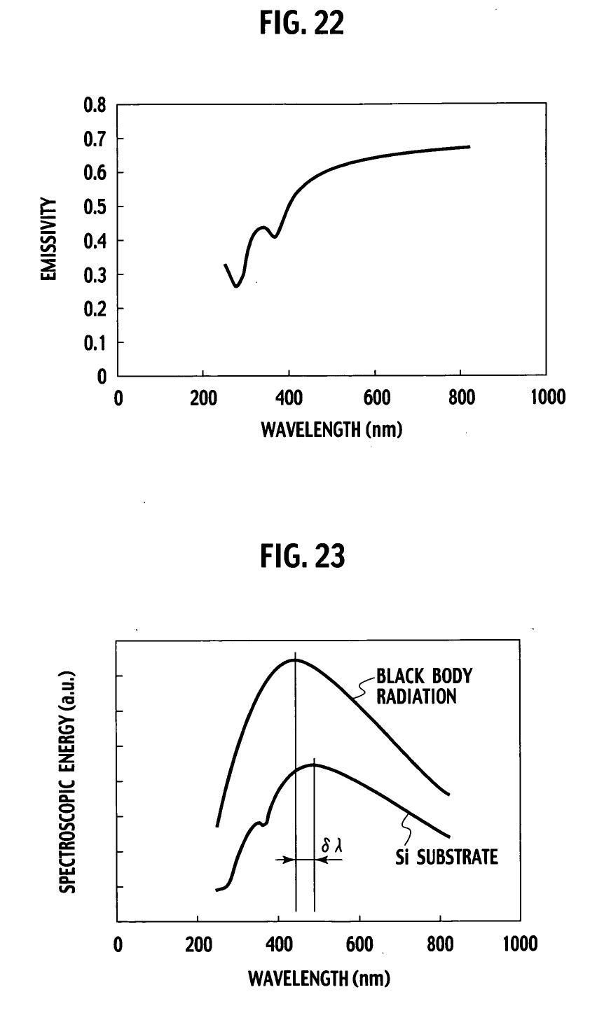

Further, within a wavelength range equal to or less than the peak wavelength λ of the flashlamp light, reflectivity of a semiconductor substrate 1, such as Si, may have large changes. For example, as shown in FIG. 22, emissivity of the Si substrate is abruptly reduced within a wavelength range of 500 nm or less. Here, the sum of emissivity and reflectivity equals one. For example, as shown in FIG. 23, a peak position of a spectroscopic energy distribution of energy received from the flashlamp light by the Si substrate is shifted to the long wavelength side by δλ with respect to a spectroscopic energy distribution of black body radiation, derived from Plank's radiation law, corresponding to a color temperature of the flashlamp light. Here, the spectroscopic energy received from the flashlamp light by the Si substrate is a product of emissivity of the Si substrate and spectral energy of the flashlamp light. Accordingly, it is possible to further improve the heat efficiency by selecting the thickness of the translucent film 14 using the peak wavelength in the spectroscopic energy distribution of the energy received from the flashlamp light by the semiconductor substrate 1, instead of the peak wavelength of the flashlamp light.

A manufacturing method for a semiconductor device according to the embodiment of the present invention will be described using a manufacturing process of a CMOS transistor as an example. Further, the semiconductor device is not limited to a CMOS transistor. A semiconductor device such as a p-MOS transistor or a n-MOS transistor is also within the scope of the invention. Additionally, a MIS transistor using an insulating film such as a SiON film, a Si₃N₄ film, or a composite insulating film between a SiO₂ film and an SiON film, an Si₃N₄ film, a various metal oxide film or the like, instead of an SiO₂ film of a MOS transistor, is also within the scope of the invention.

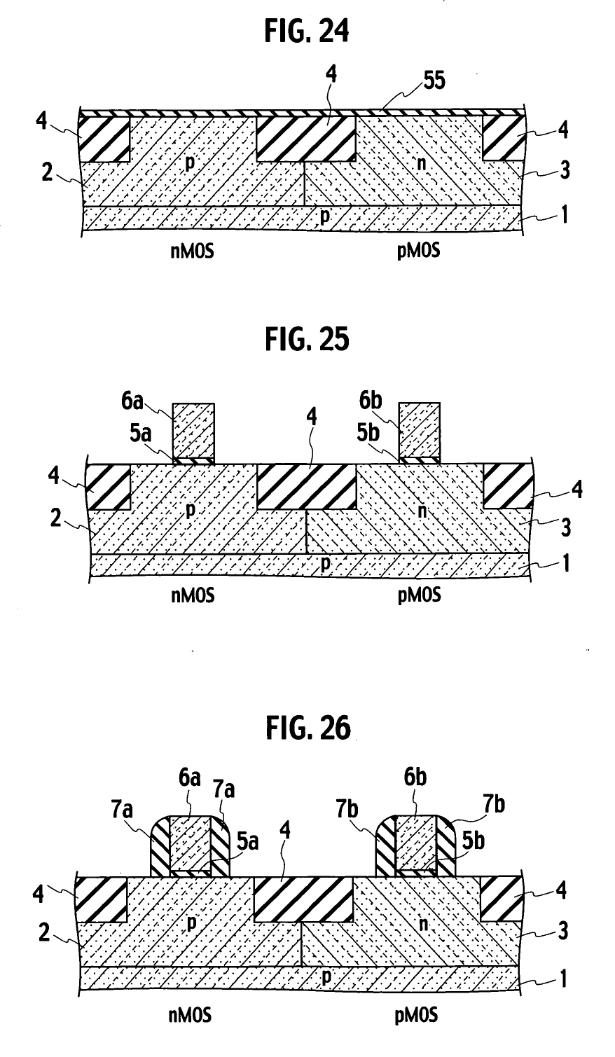

As shown in FIG. 24, a p-well 2 is formed in a nMOS region of the p-type Si semiconductor substrate 1, and a n-well 3 is formed in a pMOS region. An STI 4 as an isolation region is formed around the p-well 2 and the n-well 3. The nMOS and pMOS regions, which serve as element regions, are separated by the STI 4. Then, an insulating film 55, such as a thermal oxide film, is formed on the surface of the semiconductor substrate 1.

As shown in FIG. 25, a poly-Si film is deposited on top of the insulating film 55 by LPCVD and the like. By photolithography, RIE and the like, the poly-Si film and the insulating film 55 are selectively removed, so as to form gate electrodes 6a, 6b and gate insulating films 5a, 5b in the nMOS and PMOS regions, respectively.

As shown in FIG. 26, by LPCVD and the like, an insulating film, such as Si₃N₄, is deposited on the surface of the semiconductor substrate 1. The insulating film is selectively removed by directional etching, such as RIE and the like, so as to form sidewall spacers 7a and 7b selectively remaining on side surfaces of the gate electrodes 6a, 6b, and the gate insulating films 5a, 5b.

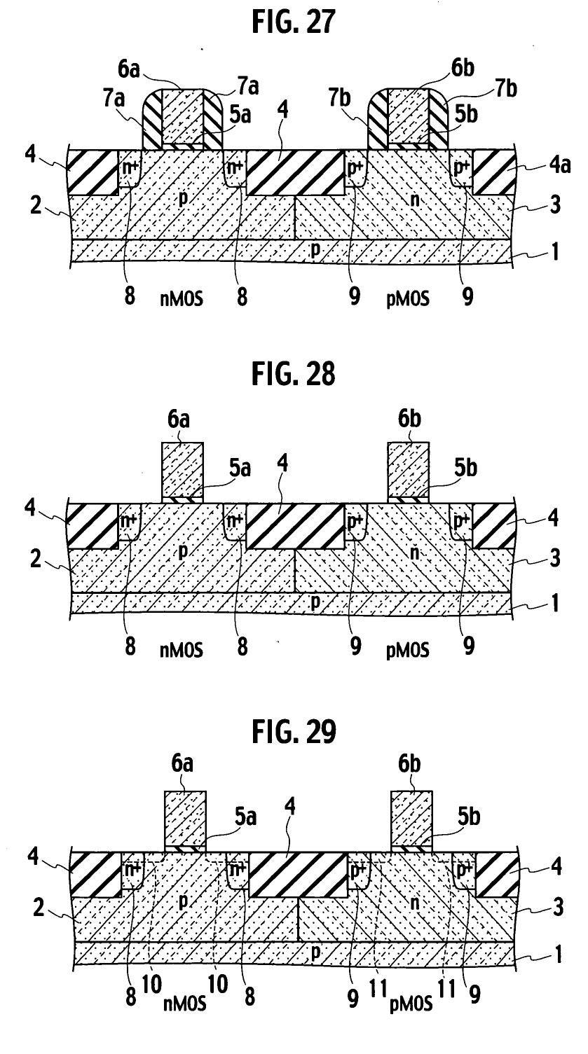

As shown in FIG. 27, by photolithography and the like, a photoresist film is formed to cover the PMOS region. Using the gate electrode 6a and the sidewall spacer 7a as a mask, group V element ions (second impurity ions), such as P ions, are selectively implanted into the NMOS region by ion implantation. Ion implantation conditions are an acceleration energy of about 10 keV and an implant dose of about 3×10¹⁵ cm⁻². The photoresist film on the PMOS region is removed.

Then, by photolithography and the like, a photoresist film is formed to cover the nMOS region. Using the gate electrode 6b and the sidewall spacer 7b as a mask, group III element ions (second impurity ions), such as B ions, are selectively implanted into the PMOS region by beam line ion implantation. Ion implantation conditions are acceleration energy of about 4 keV and an implant dose of about 3×10¹⁵ cm⁻². The photoresist film on the nMOS region is removed.

By spike RTA and the like, the P and B ions implanted in the p-well 2, the n-well 3, and the gate electrode 6a, 6b are activated at a temperature of about 1000° C. The term “spike RTA” refers to an RTA process that eliminates the time to maintain the highest attained temperature. As a result, n⁺-type source-drain regions 8 and p⁺-type source-drain regions 9 are formed between both ends of the sidewall spacer 7a, 7b and the STI 4, respectively.

As shown in FIG. 28, by wet etching using a hot phosphoric acid solution and the like, the sidewall spacers 7a, 7b are selectively removed.

As shown in FIG. 29, by photolithography and the like, a photoresist film is formed to cover the PMOS region. Using the gate electrode 6a as a mask, group V element ions (first impurity ions), such as P ions, are selectively implanted into the nMOS region by ion implantation. Ion implantation conditions are an acceleration energy of about 1.5 keV and an implant dose of about 1×10¹⁵ cm⁻². The photoresist film on the pMOS region is removed.

Then, by photolithography and the like, a photoresist film is formed to cover the nMOS region. Using the gate electrode 6b as a mask, group III element ions (first impurity ions), such as B ions, are selectively implanted into the PMOS region by ion implantation. Ion implantation conditions are acceleration energy of about 0.5 keV and an implant dose of about 1×10¹⁵ cm⁻².

As a result, impurity implanted regions 10 and 11 implanted with the P and B ions are formed in the nMOS and PMOS regions of the semiconductor substrate 1 between both ends of the gate insulating films Sa, 5b, and the STI 4, respectively.

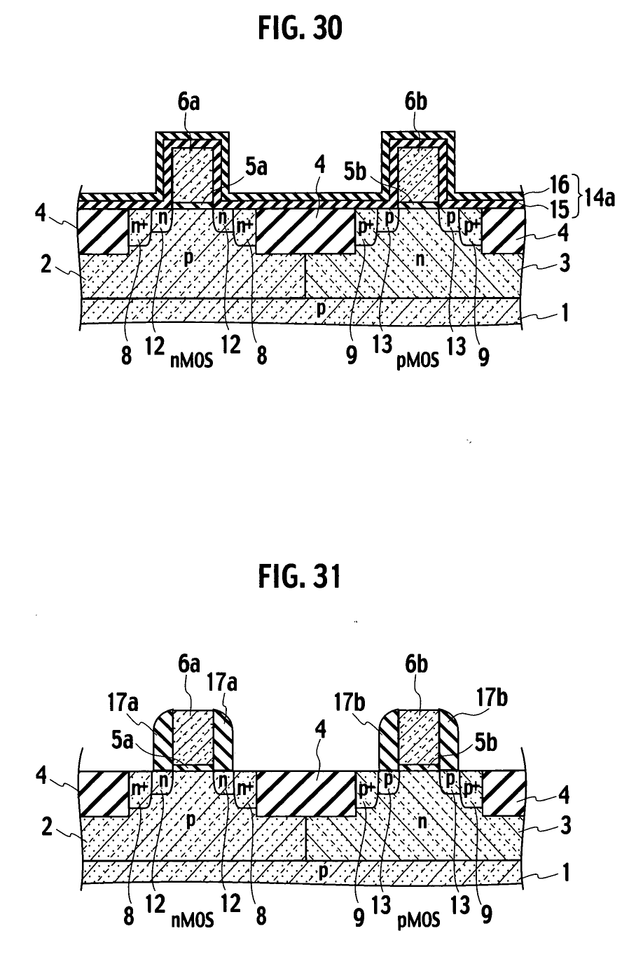

As shown in FIG. 30, by LPCVD and the like, a translucent film 14a including a first insulating film 15 and a second insulating film 16, such as Si₃N₄, is deposited on the surface of the STI 4, the impurity implanted regions 10, 11 and the gate electrode 6a, 6b. The first and second insulating films 15 and 16 are a Si₃N₄ film having a thickness of about 60 nm and a SiO₂ film having a thickness of about 80 nm, respectively, which are deposited at a temperature of about 600° C. or less.

The semiconductor substrate 1 is placed on top of the susceptor 31 of the annealing apparatus shown in FIG. 1. The semiconductor substrate 1 is preheated from the bottom surface of the semiconductor substrate 1 to about 450° C. for example, by the heat source 32 of the susceptor 31. While maintaining a preheating temperature of about 450° C. on the semiconductor substrate 1, the surface of the semiconductor substrate 1 is irradiated with flashlamp light from the light source 38 with a pulse width of about two ms and an irradiation energy density of about 25 J/cm². By activation annealing, the P and B ions in the impurity implanted regions 10, 11 diffuse to a location in substitutional lattice sites to be activated. As a result, n-type extension regions (diffusion layers) 12 and p-type extension regions (diffusion layers) 13 are formed between both ends of the gate insulating films 5a, 5b and the source-drain regions 8, 9, respectively.

As shown in FIG. 31, the first and second insulating films 15, 16 are selectively removed by directional etching such as RIE, and the like. As a result, the first and second insulating films 15, 16 are selectively remained on side surfaces of the gate electrodes 6a, 6b, and the gate insulating films 5a, 5b so as to form sidewall spacers 17a and 17b, respectively. In addition, the sidewall spacers 17a, 17b may be formed using the first insulating film 15 of Si₃N₄ by removing the second insulating film 16 of SiO₂ by wet etching using a hydrofluoric acid solution, and the like.

By sputter and the like, a metal film such as nickel (Ni) is deposited on top of the semiconductor substrate 1. By RTA and the like, silicidation of the deposited metal film is implemented on the surfaces of the gate electrodes 6a, 6b and the source-drain regions 8, 9, which are disposed between the STI 4 and the sidewall spacers 17a, 17b. By wet etching and the like, unreacted Ni is removed. An interlevel insulating film such as SiO₂, is deposited on the surface of the semiconductor substrate 1. Then, contact holes are opened in the interlevel insulating film above the gate electrodes 6a, 6b, and the source-drain regions 8, 9, respectively. Interconnections are connected to the gate electrodes 6a, 6b, and the source-drain regions 14, 15 through the contact holes, respectively. Thus, a semiconductor device having the shallow extension regions 12, 13 of about 20 nm or less is manufactured.

In a manufacturing method of a semiconductor device according to the embodiment of the present invention, the extension regions 12, 13 are activated by irradiating with the flashlamp light from the light source 38 through the translucent film 14a. The refractive indices of the first and second insulating films 15, 16 of the translucent film 14a are larger than that of the ambient gas and smaller than that of the semiconductor substrate 1. In addition, the refractive index of the second insulating film 16 on the ambient side is smaller than that of the first insulating film 15. As mentioned above, since differences in the refractive index between the ambient gas, the first and second insulating film 15, 16, and the semiconductor substrate 1 can be reduced, reflectivity at the interface of the semiconductor substrate 1 can be decreased.

Further, the flashlamp light is irradiated to the translucent film 14a which covers gate electrodes 6a and 6b and the impurity implanted regions 10, 11. Since the reflectivity of the entire surface of the semiconductor substrate 1 becomes uniform, the pattern density dependence is reduced. Thus, it is possible to suppress local heating. In this way, in the embodiment of the present invention, it is possible to suppress crystal defects generated in the semiconductor substrate 1 and to form a shallow pn junction. As a result, highly uniform semiconductor devices can be manufactured with a high yield rate.

In addition, in the source-drain regions 8, 9 in which ion implant depths of the impurities are deep compared to the extension regions 12, 13, it is difficult to recover crystal defects due to the ion implantation by ultrarapid thermal annealing, such as flashlamp annealing. In particular, dislocations or stacking faults tend to remain around the pn junction. This is because heat may not reach to a deep portion over the pn junction by ultrarapid thermal annealing. If the irradiation energy density of the flashlamp light is increased, it become possible to recover crystal defects. However, due to the thermal stress, damage, such as slips and dislocations, are generated in the semiconductor substrate 1, and thus a production yield is decreased. Consequently, activation annealing for the source-drain regions 8, 9 is carried out by spike RTA to recover the crystal defects due to the ion implantation. In the deep source-drain regions 8, 9, since thermal diffusion is not a serious problem, spike RTA, which requires a longer time than flashlamp annealing, can be used.

After forming the deep source-drain regions 8, 9, the shallow extension regions 12, 13 are formed. In the shallow extension regions 12, 13, since the thermal diffusion is a serious problem, spike PTA cannot be used. Thus, an ultrarapid thermal annealing technique is inevitable. Since the impurity implanted regions 10, 11 are shallow, i.e., about 20 nm or less, heat can be transmitted throughout the impurity implanted regions 10, 11 even by ultrarapid thermal annealing. As a result, the crystal defects generated around the impurity implanted regions 10, 11 may be easily recovered. As mentioned above, the source-drain regions 8, 9 and the extension regions 12, 13 can reduce the crystal detects to active impurities at high concentration, and thus it is possible to improve transistor performance.

### Other Embodiments

In the embodiment of the present invention, a Xe flashlamp is used as the light source 38 shown in FIG. 1. However, the light source 38 is not limited to a Xe flashlamp. As the light source 38, a flashlamp using a gas, such as other noble gases, mercury (Hg), and hydrogen (H₂), and a Xe arc discharge lamp, which can emit a high intensity light ranging from a near-ultraviolet region to a near-infrared region, may be used. Additionally, as the light source 38, a laser, such as an excimer laser, a YAG laser, a carbon monoxide (CO) gas laser, a carbon dioxide (CO₂) gas laser, which can emit a coherent high intensity light within a wavelength range from near-ultraviolet region to near-infrared region, may be used.

Various modifications will become possible for those skilled in the art after storing the teachings of the present disclosure without departing from the scope thereof.

What is claimed is:

1. A method for annealing by light irradiation, comprising:
depositing a translucent film with a predetermined thickness on a semiconductor substrate, the translucent film having a refractive index smaller than the refractive index of the semiconductor substrate, the thickness defined by a peak wavelength of the light and the refractive index of the translucent film;
heating the semiconductor substrate in a temperature range of about 300° C. to about 600° C.; and
heating a surface of the semiconductor substrate with the light, the light having a pulse width of about 0.1 ms to about 100 ms.

2. The method of claim 1, wherein the thickness satisfies a condition defined by:
(2j−1)*λ/(4n)−λ/(8n)<d<(2j−1)*λ/(4n)+λ/(8n),
where d is the thickness, n is the refractive index of the translucent film, λ is the peak wavelength, and j is an arbitrary positive integer.

3. The method of claim 1, wherein the thickness satisfies a condition defined by:
λ/(4n)−λ/(8n)<d<λ/(4n)+λ/(8n)
where d is the thickness, n is the refractive index of the translucent film, and λ is the peak wavelength.

4. The method of claim 1, wherein the thickness is not less than 3λ/(4n), where n is the refractive index of the translucent film, λ is the peak wavelength.

5. The method of claim 1, wherein the translucent film includes:
a first insulating film deposited on the semiconductor substrate; and
a second insulating film deposited on the first insulating film,
the first insulating film having a thickness d₁ and a refractive index n₁, the second insulating film having a thickness d₂ and a refractive index n₂ that is smaller than the refractive index n₁.

6. The method of claim 1, wherein the translucent film is one of a silicon oxide film, a silicon nitride film, and a carbon doped silicon oxide film.

7. The method of claim 1, wherein the light is irradiated at an irradiation energy density in a range of about 5 J/cm² to about 100 J/cm².

8. The method of claim 1, wherein the light is one of a flashlamp light and a laser light.

9. The method of claim 5, wherein the thicknesses d₁ and d₂ satisfy conditions defined by:
(2j−1)*λ/(4n₁)−λ/8n₁)<d₁<(2j−1)*λ/(4n₁)+λ/(8n₁), and
(2k−1)*λ/(4n₂)−λ/(8n₂)<d₂<(2k−1)*λ/(4n₂)+λ/(8n₂).
where λ is the peak wavelength, and j and k are arbitrary positive integers.

10. A method for manufacturing a semiconductor device, comprising:
forming a gate insulating film on a semiconductor substrate;
forming a gate electrode on the gate insulating film;
implanting first impurity ions into the semiconductor substrate using the gate electrode as a mask;
depositing a translucent film with a predetermined thickness on the semiconductor substrate, the translucent film having a refractive index smaller than the refractive index of the semiconductor substrate;
heating the semiconductor substrate in a temperature range of about 300° C. to about 600° C.; and
heating a surface of the semiconductor substrate with a light so as to activate the first impurity ions, the light having a pulse width of about 0.1 ms to about 100 ms;
wherein the thickness of the translucent film is defined by a peak wavelength of the light and the refractive index of the translucent film.

11. The method of claim 10, wherein the thickness satisfies a condition defined by:
(2j−1)*λ/(4n)−λ/(8n)<d<(2j−1)*λ/(4n)+λ/(8n),
where d is the thickness, n is the refractive index of the translucent film, λ is the peak wavelength, and j is an arbitrary positive integer.

12. The method of claim 10, wherein the thickness satisfies a condition defined by:
λ/(4n)−λ/(8n)<d<λ/(4n)+λ/(8n),
where d is the thickness, n is the refractive index of the translucent film, and λ is the peak wavelength.

13. The method of claim 10, wherein the thickness d is not less than 3λ/(4n), where n is the refractive index of the translucent film, and λ is the peak wavelength.

14. The method of claim 10, wherein the translucent film includes a first insulating film deposited on the semiconductor substrate and a second insulating film deposited on the first insulating film, the first insulating film having a thickness d₁ and a refractive index n₁, the second insulating film having a thickness d₂ and a refractive index n₂ that is smaller than the refractive index n₁.

15. The method of claim 10, wherein the translucent film is one of a silicon oxide film, a silicon nitride film, and a carbon doped silicon oxide film.

16. The method of claim 10, wherein the light is irradiated at an irradiation energy density in a range of about 5 J/cm² to about 100 J/cm².

17. The method of claim 10, wherein the light is one of a flashlamp light and a laser light.

18. The method of claim 10, further comprising:
forming a source-drain region by activating second impurity ions before implanting the first impurity ions, including;
forming a sidewall spacer on a side surface of the gate electrode;
implanting the second impurity ions into the semiconductor substrate using the gate electrode and the sidewall spacer as a mask; and
heating the semiconductor substrate.

19. The method of claim 10, further comprising:
forming a second sidewall spacer on the side surface of the gate electrode by selectively removing the translucent film after activating the first impurity ions.

20. The method of claim 14, wherein the thicknesses d₁ and d₂ satisfy conditions defined by:
(2j−1)*λ/(4n₁)−λ/8n₁)<d₁<(2j−1)*λ/(4n₁)+λ/(8n₁), and
(2k−1)*λ/(4n₂)−λ/(8n₂)<d₂<(2k−1)*λ/(4n₂)+λ/(8n₂),
where λ is the peak wavelength, and j and k are arbitrary positive integers.
